(19) United States
(12) Patent Application Publication
(10) Pub. No.: US 2025/0364484 A1
(43) Pub. Date: Nov. 27, 2025

(54) BONDING ARRANGEMENT HAVING A METAL INVERSE OPALS LAYER

(71) Applicant: Purdue Research Foundation, West Lafayette, IN (US)

(72) Inventors: Tiwei Wei, Lafayette, IN (US); Shuhang Lyu, West Lafayette, IN (US); Keyu Wang, West Lafayette, IN (US)

(73) Assignee: Purdue Research Foundation, West Lafayette, IN (US)

(21) Appl. No.: 19/213,136

(22) Filed: May 20, 2025

Related U.S. Application Data
(60) Provisional application No. 63/651,427, filed on May 24, 2024.

(51) Int. Cl. H01L 23/00; H01L 25/065

(52) U.S. Cl. CPC H01L 24/81; H01L 24/11; H01L 24/13; H01L 24/16; H01L 24/27; H01L 24/29; H01L 24/32; H01L 24/83; H01L 25/0657; H01L 2224/11001; H01L 2224/11462; H01L 2224/1147; H01L 2224/13082; H01L 2224/13111; H01L 2224/13247; H01L 2224/13499; H01L 2224/16145; H01L 2224/16507; H01L 2224/27001; H01L 2224/27462; H01L 2224/2747; H01L 2224/29082; H01L 2224/29111; H01L 2224/29247; H01L 2224/29499; H01L 2224/32145; H01L 2224/32507; H01L 2224/81203; H01L 2224/83203; H01L 2225/06513; H01L 2225/06524; H01L 2924/381; H01L 2924/3841

(57) ABSTRACT

A method of bonding two substrates together includes applying a plurality of templating spheres to a first metal layer on a first substrate of the two substrates, applying a metal on the plurality of templating spheres to form a porous metal layer, and bonding a solder layer arranged on a second substrate of the two substrates to the porous metal layer with heat and pressure such that pores of the porous metal layer are filled with solder material and intermetallic compounds, forming a metal inverse opals layer bonding the first and second substrates together.

This application claims priority to U.S. Provisional Application Ser. No. 63/751,527 entitled “Copper Microporous-Assisted Bonding for Fine-Pitch Cu/Sn Microbump 3D Interconnects” filed May 24, 2024, the disclosure of which is incorporated herein by reference in its entirety.

### FIELD

This disclosure relates generally to bonding arrangements for semiconductors, and, more particularly, to microbump bonding arrangements for semiconductors.

### BACKGROUND

Advanced semiconductor packaging technologies have become increasingly important to improving the performance, functionality, and integration density of modern electronic systems. As computing demands continue to escalate, three-dimensional (3D) integration using fine-pitch, high-density interconnects and multi-chip stacking architectures offers a promising path forward. Among these, microbump bonding has gained widespread use in die-level interconnection platforms (e.g., die-to-die, die-to-interposer). Conventional microbump pitches typically range from 30-50 μm, but scaling down to pitches of less than 10 μm could provide significantly higher interconnect densities—by factors of up to 100—resulting in enhanced data throughput and system performance. However, the miniaturization of microbumps introduces numerous challenges, including inter-bump shorting, bonding interface co-planarity issues, and concerns surrounding electrical and mechanical reliability. These issues are exacerbated during thermocompression bonding, during which the molten solder may collapse or bridge neighboring bumps, and further, during which the bonding layer's thermal conductivity becomes a limiting factor for heat dissipation in densely stacked 3D systems.

One solution to address these issues includes the incorporation of porous metal interlayers, such as copper (Cu) and nickel (Ni), into solder joints. Porous metals offer a combination of high thermal conductivity and advantageous mechanical properties. Studies involving porous copper structures in SAC305 and Sn58Bi solder systems have shown that these interlayers promote intermetallic compound (IMC) formation and robust metallurgical bonding by enabling molten solder infiltration into the porous matrix. Variants such as chemically de-alloyed nanoporous copper and etched copper foams have demonstrated superior bonding performance, reduced bonding time, and enhanced mechanical strength. Moreover, incorporating dual-layer porous Cu/Ni structures and novel designs like nickel micro-nano cones has been shown to mitigate oxidation and enable fluxless bonding at relatively low temperatures, further supporting the potential of porous interlayers in fine-pitch applications.

Despite promising results, however, existing porous metal structures have been usable only in solder balls with dimensions of between 500-800 μm, which remain incompatible with microbump-level interconnects. The size and scale of current porous copper foams, meshes, and lotus-type sheets, ranging from 600 μm to 1 mm, limit their direct integration into sub-10 μm microbump bonding systems. Accordingly, there is a need for an interconnect technology that combines fine-pitch compatibility with the performance benefits of porous metal reinforcement.

### SUMMARY

In some aspects, the techniques described herein relate to a method of bonding two substrates together including applying a plurality of templating spheres to a first metal layer on a first substrate of the two substrates and applying a metal on the plurality of templating spheres to form a porous metal layer. The method further includes bonding a solder layer arranged on a second substrate of the two substrates to the porous metal layer with heat and pressure such that pores of the porous metal layer are filled with solder material and intermetallic compounds, forming a metal inverse opals layer bonding the first and second substrates together.

In another embodiment, a method of forming a copper inverse opals layer of a substrate bonding arrangement includes applying a plurality of templating spheres to a first metal layer on a first substrate by sedimentation, sintering the plurality of templating spheres, applying a copper on the plurality of templating spheres to form a porous metal layer, dissolving the plurality of templating spheres, and bonding the porous metal layer to a solder layer under heat and compression such that solder material from the solder layer infiltrates pores of the porous metal layer to form the copper inverse opals layer.

In some aspects, the techniques described herein relate to a bonding arrangement for bonding two substrates together including a solder layer and a metal inverse opal layer including a plurality of unit cells, each unit cell including a metal inverse opal structure having pores filled with solder material, and intermetallic compounds formed at interfaces between the solder material and metal of the metal inverse opal structure.

### BRIEF DESCRIPTION OF THE DRAWINGS

FIG. 1 is a schematic cross-sectional view of a chip structure having a bonding arrangement that includes a metal inverse opal-based bonding layer.

FIG. 2 is a schematic perspective view of a unit cell of the metal inverse opal layer of FIG. 1.

FIG. 3 is a process diagram of a method for bonding two substrates together.

FIG. 4A is a schematic cross-sectional view of a substrate having a sputter barrier and seed layer applied.

FIG. 4B is a schematic cross-sectional view of the substrate of FIG. 4A having a photoresist applied.

FIG. 4C is a schematic cross-sectional view of the substrate of FIG. 4B after applying of a metal layer.

FIG. 5A is a schematic cross-sectional view of the substrate of FIG. 4C after application of a plurality of templating spheres.

FIG. 5B is a schematic cross-sectional view of the substrate of FIG. 5A after applying metal to the templating spheres to form a metal inverse opals layer.

FIG. 5C is a schematic cross-sectional view of the substrate of FIG. 5B after removing the templating spheres and photoresist.

FIG. 6A is a schematic cross-sectional view of the substrate of FIG. 4C after application of a solder layer.

FIG. 6B is a schematic cross-sectional view of the substrate of FIG. 6A after removing the photoresist.

FIG. 7 is a schematic cross-sectional view of the substrates of FIGS. 5C and 6B bonded together.

FIG. 8 depicts (a) an SEM top view of the CIO based microporous metal structure; (b), SEM side view of the CIO based microporous metal structure on the Cu microbump; (c)-(e) enlarged SEM views of the CIO porous structure with a small pore size of 3 μm on a 100 μm Cu bump diameter; and (f) an FIB image of the 1-layer CIO structure electrodeposited on the Cu microbump.

### DETAILED DESCRIPTION

For the purposes of promoting an understanding of the principles of the embodiments described herein, reference is now made to the drawings and descriptions in the following written specification. No limitation to the scope of the subject matter is intended by the references. This disclosure also includes any alterations and modifications to the illustrated embodiments and includes further applications of the principles of the described embodiments as would normally occur to one skilled in the art to which this document pertains.

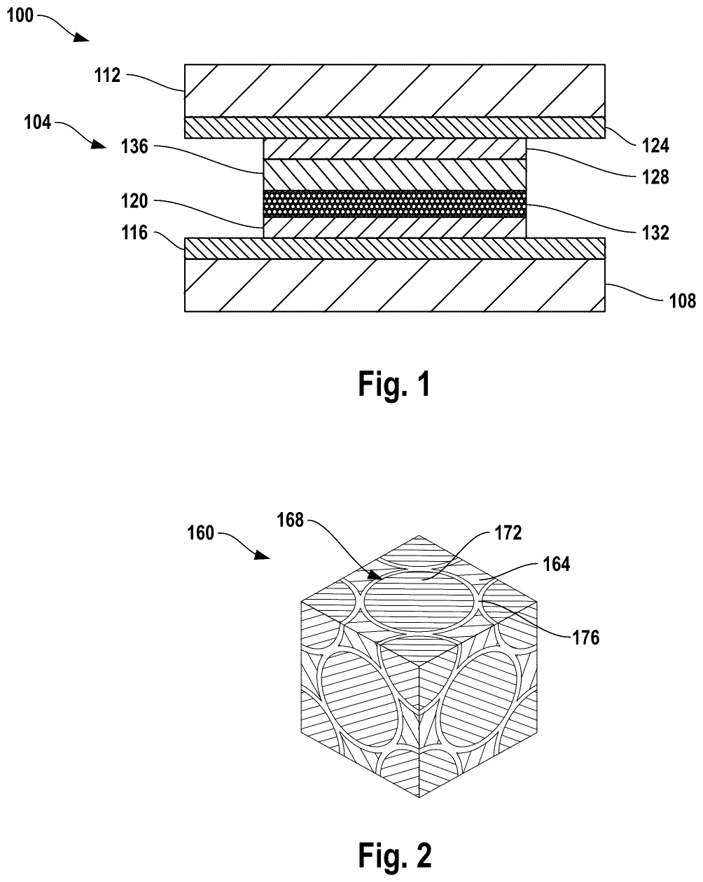

FIG. 1 illustrates a schematic diagram of a chip structure 100 including a bonding arrangement 104 that includes a metal-based inverse opals structure. An inverse opal structure refers to a periodic porous network formed by templating spherical particles and subsequently removing the template to create interconnected voids. The inverse opal structure may be, in particular, formed by an ordered array of the templating spherical particles. In the embodiment described herein, the metal-based structure is a copper inverse opals (CIO) structure, though the reader should appreciate that the metal inverse opals structure may be formed of other metal materials, in particular metals commonly used in semiconductors. For example, the metal inverse opals structure may be formed of one or more of cobalt, nickel, zinc, gallium, silver, platinum, gold, an alloy of the aforementioned metals, or another suitable metal or metal alloy.

The chip structure 100 includes a bottom die or substrate 108 and a top die or substrate 112, which are connected to one another via the bonding arrangement 104. The top and bottom substrates 108, 112 may be, for example, silicon substrates that are, for example, layers of a semiconductor chip.

The bonding arrangement 104 includes at least one metal layer 116, 120, 124, 128, two of which are shown, on each substrate 108, 112 arranged on a side of the respective substrate 108, 112 facing toward the other substrate 112, 108. The metal layers 116, 120, 124, 128 may be formed of the same metal, for example copper, nickel, cobalt, etc., or the inner metal layers 120, 128 may be formed of one metal, for example copper, while the outer metal layers 116, 124 may be formed of a different metal, for example nickel or cobalt. In some embodiments, the metal layers 116, 120 formed on one of the substrates 108 may be different form the metal layers 124, 128 formed on the other substrate 112. Each of the metal layers 116, 120, 124, 128 may be formed of any suitable semiconductor-compatible metal.

The bonding arrangement 104 further includes an inverse opals metal layer 132 and a solder layer 136. The inverse opals metal layer 132 is formed as a highly ordered periodic array with a plurality of unit cells 160, one of which is shown in FIG. 2. Each unit cell 160 is formed of the metal structure 164 having pores 168 therein. The pores 168 may have, for example, a diameter of less than 5 μm. In another embodiment, the pores 168 may have a diameter of between approximately 100 nm and approximately 5 μm. In a further embodiment, the pores 168 may have a diameter of between approximately 200 nm and approximately 1 μm. The pore size may be caried depending on the overall size of the bonding arrangement 104 and the desired characteristics of the inverse opals metal layer 132.

Each of the pores 168 is filled with solder 172 and, at the interfaces between the metal structure 164 and the solder 172, intermetallic compounds (IMCs) 176, which include a combination of the metal and the solder material. In particular, the inverse opals metal layer 132 may be a copper inverse opal (CIO) layer in which the metal structure 164 is copper. Further, the solder material is, in some embodiments, a tin-containing or tin-based solder material, for example elemental tin or a tin alloy such as tin-lead, tin-silver-copper (SAC), in particular SAC305, or Sn58Bi. As used herein, tin refers to elemental tin or any tin-containing soldering alloy. Alternatively, any other desired solder material may be used in the solder layer. The IMCs may include or consist of, for example, Cu₃Sn and/or Cu₆Sn₅.

The bonding arrangement 104 is formed as part of a microbump bond between the two substrates 108, 112. In particular, the bonding arrangement 104 includes a plurality of the microbump bonds, each of which connects the two substrates 108, 112. Each microbump of the bonding arrangement 104 may have a diameter of less than 100 μm. In some embodiments, each microbump has a diameter of from 5 μm to 100 μm, and in one embodiment, a diameter of approximately 20 μm. The microbumps may, in some embodiments, have a pitch, or distance between adjacent microbumps, of less than approximately 10 μm such that the microbumps are considered fine-pitch microbumps. In addition, the thickness of the microbumps may be, in various embodiments, between approximately 3 μm and approximately 5 μm. The size of the microbump bonds may vary in different embodiments depending on the desired properties of the bonding arrangement 104 and the structures being bonded. In some embodiments, the bonding arrangement 104 may be used to connect substrates as part of the back-end-of-line (BEOL) process in the manufacturing of a low-temperature complementary metal-oxide-semiconductor (CMOS).

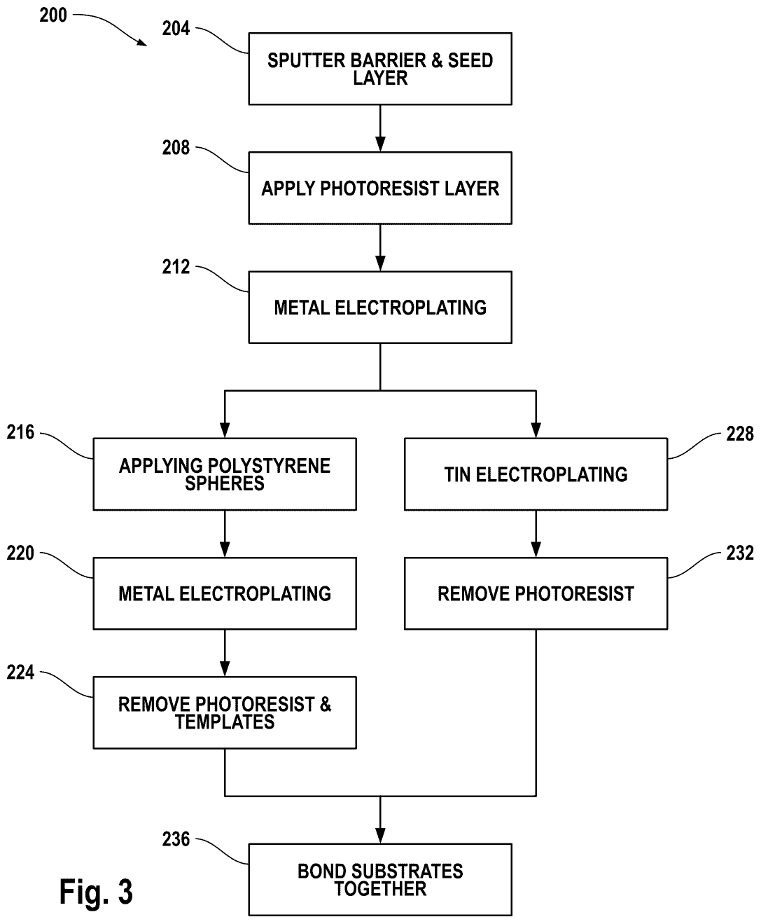

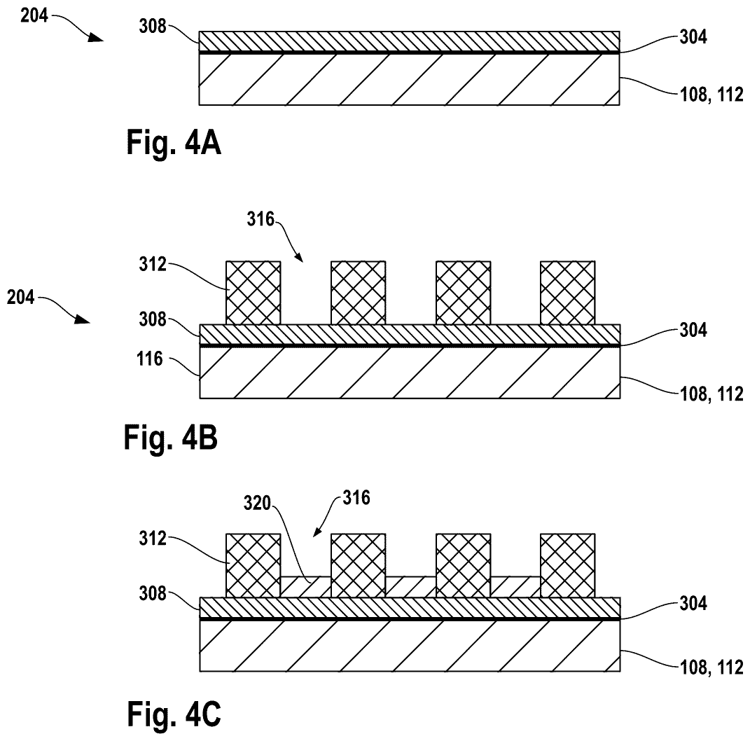

FIG. 3 illustrates a method 200 for producing the chip structure 100 and bonding arrangement 104 of FIG. 1. The method 200 begins with applying a sputter barrier 304 and seed layer 408, which forms one of the metal layers 116, 128, to the to the substrate 108, 112 (block 204), as shown in FIG. 4A. Specifically, in one embodiment, a silicon oxide layer is applied as the sputter barrier 304, and a titanium/copper barrier layer/seed layer 408 is applied by sputtering. The silicon oxide seed layer may be, in one embodiment, approximately 100 nm, while the barrier layer and seed layer may be, for example, approximately 50 nm and 150 nm, respectively.

Next, the method 200 proceeds with applying a photoresist layer 312 to the seed layer 308 (block 208), as shown in FIG. 4B, to define the size and shape of the microbumps. In particular, the photoresist layer 312 is patterned with the desired configuration of the microbumps forming the bonding arrangement 104, and is configured to be at least as thick as the copper or tin bump. For example, in one embodiment, the photoresist layer 312 may be approximately 6-10 μm. The cavities 316 in the photoresist layer form the location at which the microbumps will be arranged, and may have, for example, any desired diameter. In particular, the cavities 316 may have a diameter corresponding to the diameter of the microbumps, as described above.

The method 200 continues with applying metal electroplating of a metal layer 320, which forms one of the metal layers 120, 124, in the cavities 316 formed in the photoresist layer 312 (block 212), as shown in FIG. 4C. The metal layer 320 may be, for example, a copper layer.

After the applying of the metal electroplating, the method 200 diverges depending on whether the partial structure is to have the solder layer 136 or the inverse opals metal layer 132. The portion of the method 200 including the inverse opals metal layer 132 will be described first.

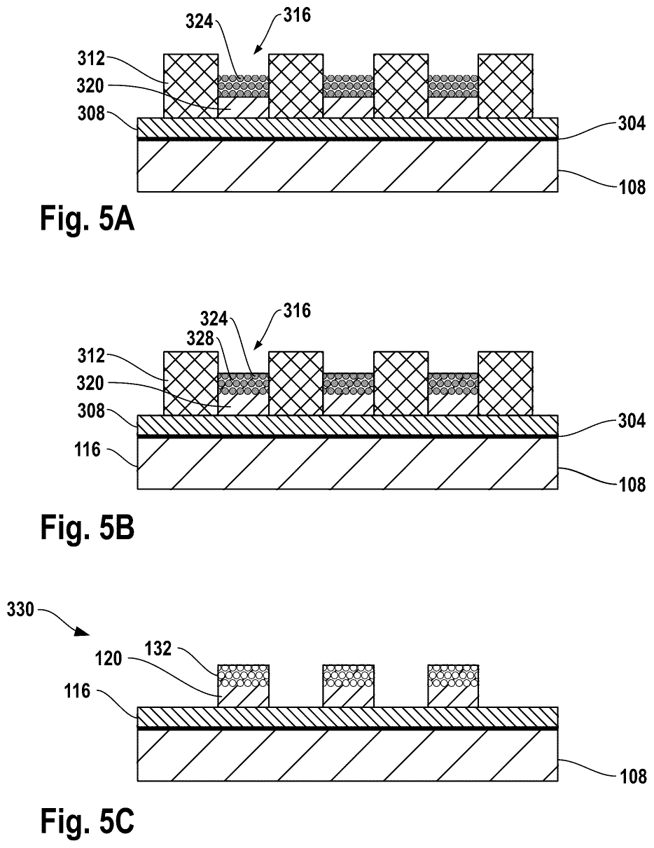

For the side of the bonding arrangement 104 including the inverse opals metal layer 132, the method 200 then continues with the application of templating spheres 324 onto the metal layer 116 (block 216), shown in FIG. 5A. The templating spheres 324 may be formed of, for example, at least one of polystyrene spheres, PMMA (polymethyl methacrylate) spheres, and SiO₂ (silica) nanoparticles. Initially, a template is generated using self-assembled templating spheres having the desired diameters. Specifically, the templating spheres 324 may be applied by a sedimentation process with a mixture of templating sphere/water suspension and DI water, and then heated such that the templating spheres self-assemble and the water evaporates, leaving the spheres forming an ordered array in each of the cavities 316. In one embodiment, the plurality of templating spheres 324 may have approximately uniform diameters, i.e. within +/−10%, and the diameter of each of the templating spheres 324 may be less than 5 μm, and in another embodiment between approximately 100 nm and approximately 5 μm. In yet another embodiment, the approximately uniform diameters may be between approximately 200 nm and approximately 1 μm.

The application of the templating spheres 324 (block 216) then includes sintering the templating spheres so as to form interconnects between adjacent ones of the templating spheres 324. In one embodiment, the templating spheres 324 may be annealed in an oven to form necks between the templating spheres 324. In one particular embodiment, for example, the templating spheres 324 formed as polystyrene spheres are sintered for 1.5 hours at 110° C. The diameter of the necks between the templating spheres 324 can be adjusted by controlling the sintering time and temperature. In particular, controlling the neck diameter allows for precise control over the porosity in the resulting inverse opals metal layer 132 since larger necks result in a more compact arrangement of the templating spheres because there are more templating spheres per unit volume, which results in more pores per unit volume.

The method continues 200 with electroplating a porous metal layer 328 the interconnected templating spheres 324 with the metal that will form the metal inverse opals layer 132 (block 220), as shown in FIG. 5B. In one embodiment, the electroplating is performed using a copper electroplating process. More specifically, in one embodiment, the electroplating process can be carried out at approximately 0.4 amps per square decimeter for 20 minutes to achieve a copper thickness of approximately 6 μm. In another embodiment, for example, the copper electroplating may be conducted at a current density of 4 amps per square decimeter (ASD) for 8 minutes, producing a copper layer with a thickness of approximately 4-6 μm.

Then, the photoresist layer 312 and templating spheres 324 are removed (block 224), leaving the completed first portion 330 of the chip structure 100 shown in FIG. 5C. The photoresist layer 312 and templating spheres 324 may be chemically dissolved by submerging the structure in a solvent, for example tetrohydrofuran.

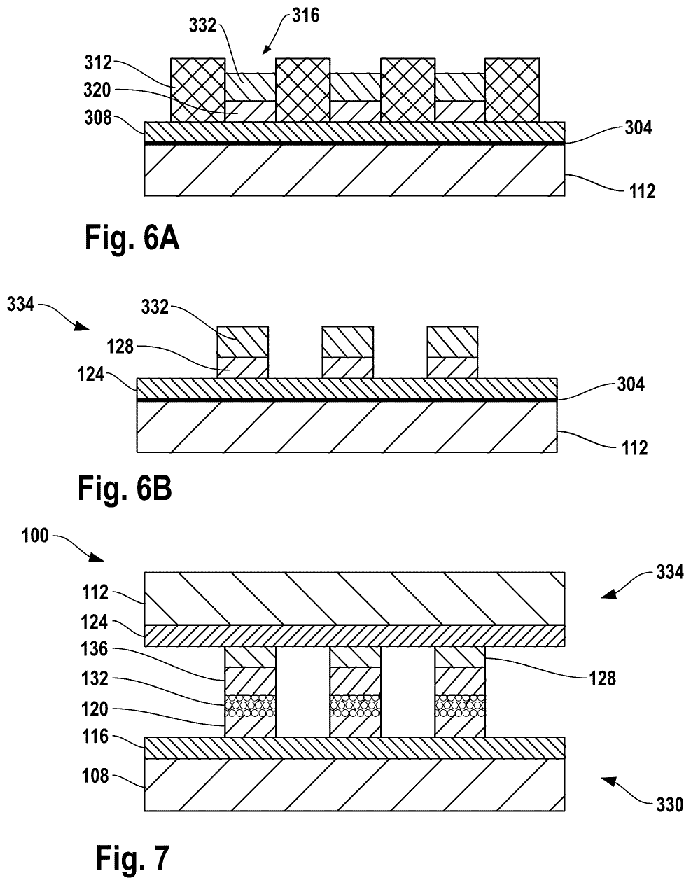

Alternatively, for the portion of the chip structure 100 having the solder layer 136, the method 200 continues from the metal electroplating (block 212 and FIG. 4C) to electroplating a solder layer 432, for example a tin-containing solder layer, on the metal layer 320 in the cavities 416 (block 228), shown in FIG. 6A. The solder layer 332 may be applied, for example, at a thickness of approximately 6 μm to approximately 10 μm. In one embodiment, for example, the tin electroplating is performed at 1 ASD for 20 minutes at 50° C., targeting a tin layer thickness of approximately 6-10 μm. Then, the photoresist is dissolved (block 232), leaving the completed second portion 334 of the chip structure 100 shown in FIG. 6B.

The method 200 concludes with bonding the first and second chip portions 330, 334 together (block 236), as shown in FIG. 7. In particular, thermocompression is used to bond the solder layer 332 to the porous metal layer 328 under heat and pressure. The heat and pressure applied is sufficient to at least partially melt the solder layer 332. Thus, during the bonding, the partially melted solder layer 332 infiltrates into the pores of the porous metal layer 328, forming the inverse opals metal structure depicted in FIG. 2. In one embodiment, the first portion 330 is heated to a temperature of approximately 280° C., while the second portion 334 is heated to a temperature of approximately 410° C., and the two portions 330, 334 are compressed with a bonding force of approximately 0.1 to 0.2 MPa.

In addition, because the solid-liquid interdiffusion (SLID) process involves operating at a temperature above the melting point of tin, the intermetallic compounds 176 are formed between the metal and the solder with significantly higher melting points. For example, when copper is used as the metal of the inverse opals metal layer 132, the resulting bonding interface structure may include Cu/Cu₃Sn/Cu, which provides high-temperature stability in the final assembly. The evolution of the IMCs 176 at the interface between the copper and tin solder during the Cu—Sn SLID process follows a sequence from scallop-like Cu₆Sn₅ to layered Cu₃Sn and ultimately porous Cu₃Sn.

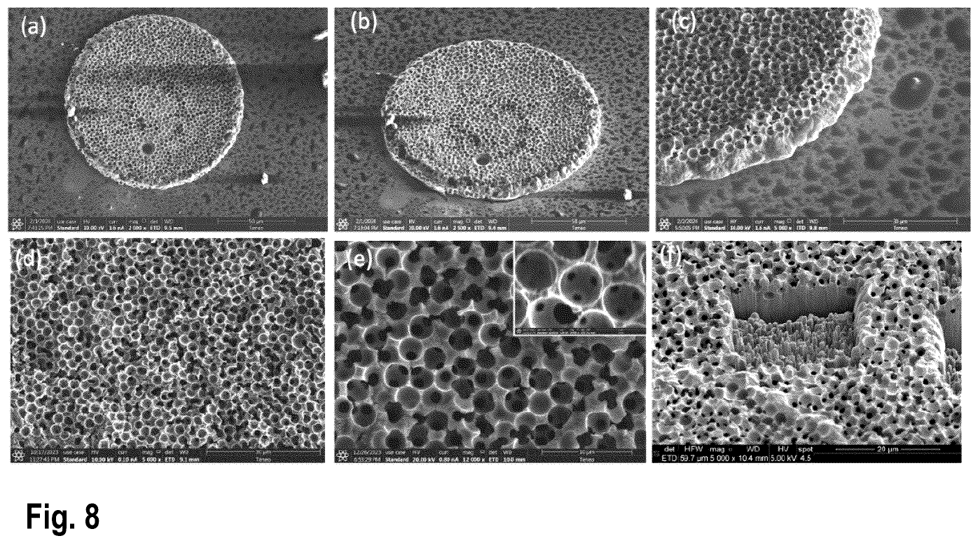

FIG. 8 illustrates scanning electron microscope (SEM) and focused ion beam (FIB) images of experimental results of the microporous structure of copper inverse opals (CIO) based microporous structure on a copper microbump. In particular, illustration (a) shows an SEM top view of the CIO based microporous metal structure, illustration (b) shows an SEM side view of the CIO based microporous metal structure on the Cu microbump, illustrations (c)-(e) show enlarged SEM views of the CIO porous structure with a small pore size of 3 μm on a 100 μm Cu bump diameter, and illustration (f) shows an FIB image of the 1-layer CIO structure electrodeposited on the Cu microbump.

The present disclosure introduces a copper microporous insertion bonding technique utilizing micro-to nanoscale porous structures embedded within Sn-based solder microbumps. This bonding method, suitable for low-temperature CMOS back-end-of-line (BEOL) processes, achieves critical pore sizes as small as 200 nm or less, thereby enhancing thermal conductivity and mechanical integrity while suppressing inter-bump shorting in 3D chip stacking architectures.

It will be appreciated that variants of the above-described and other features and functions, or alternatives thereof, may be desirably combined into many other different systems, applications or methods. Various presently unforeseen or unanticipated alternatives, modifications, variations or improvements may be subsequently made by those skilled in the art that are also intended to be encompassed by the foregoing disclosure.

What is claimed is:

1. A method of bonding two substrates together comprising:
applying a plurality of templating spheres to a first metal layer on a first substrate of the two substrates;
applying a metal on the plurality of templating spheres to form a porous metal layer; and
bonding a solder layer arranged on a second substrate of the two substrates to the porous metal layer with heat and pressure such that pores of the porous metal layer are filled with solder material and intermetallic compounds, forming a metal inverse opals layer bonding the first and second substrates together.

2. The method of claim 1, wherein the applying of the metal includes applying copper.

3. The method of claim 2, wherein the applying of the copper includes electroplating the copper around the plurality of templating spheres.

4. The method of claim 3, further comprising dissolving the plurality of templating spheres after applying the metal.

5. The method of claim 4 wherein the applying of the plurality of templating spheres further comprises sintering the plurality of templating spheres.

6. The method of claim 5, wherein the applying of the plurality of templating spheres includes applying the plurality of templating spheres using a sedimentation process before the sintering of the plurality of templating spheres.

7. The method of claim 6, further comprising, before applying the plurality of templating spheres:
applying a second metal layer on the first substrate; and
applying the first metal layer on the second metal layer.

8. The method of claim 1, further comprising, before applying the first metal layer, applying a photoresist layer defining a size and shape of the first metal layer and the metal inverse opals layer.

9. The method of claim 8, wherein the photoresist layer is applied to form a plurality of microbumps, each having a diameter of less than 10 μm.

10. The method of claim 1, wherein the plurality of templating spheres are formed of at least one of polystyrene, polymethyl methacrylate, and SiO₂ nanoparticles.

11. The method of claim 1, wherein the plurality of templating spheres have an approximately uniform diameter.

12. The method of claim 11, wherein the approximately uniform diameter is between approximately 100 nm and approximately 5 μm.

13. The method of claim 1, wherein the metal comprises one or more of copper, nickel, cobalt, silver, gold, or an alloy of at least one of copper, nickel, cobalt, silver, or gold.

14. A method of forming a copper inverse opals layer of a substrate bonding arrangement comprising:
applying a plurality of templating spheres to a first metal layer on a first substrate by sedimentation;
sintering the plurality of templating spheres;
applying a copper on the plurality of templating spheres to form a porous metal layer;
dissolving the plurality of templating spheres; and
bonding the porous metal layer to a solder layer under heat and compression such that solder material from the solder layer infiltrates pores of the porous metal layer to form the copper inverse opals layer.

15. A bonding arrangement for bonding two substrates together comprising:
a solder layer; and
a metal inverse opal layer comprising a plurality of unit cells, each unit cell including a metal inverse opal structure having pores filled with solder material, and intermetallic compounds formed at interfaces between the solder material and metal of the metal inverse opal structure.

16. The bonding arrangement of claim 15, wherein the solder layer and the metal inverse opal layer are formed as a plurality of microbumps, each of which has a diameter of less than 10 μm.

17. The bonding arrangement of claim 15, wherein the metal is copper and the solder material is tin or a tin-containing alloy.

18. The bonding arrangement of claim 17, wherein the intermetallic compounds include Cu₃Sn.

19. The bonding arrangement of claim 15, wherein the pores have an approximately uniform diameter.

20. The bonding arrangement of claim 19, wherein the approximately uniform diameter is between approximately 100 nm and approximately 5 μm.
